(19) United States
(12) Patent Application Publication
(10) Pub. No.: US 2026/0305198 A1
(43) Pub. Date: Oct. 1, 2026

(54) SEMICONDUCTOR STRUCTURE AND METHOD FOR FORMING THE SAME

(71) Applicant: VisEra Technologies Company Limited, Hsin-Chu City (TW)

(72) Inventors: Yi-Hua CHIU, Hsin-Chu City (TW); Ming-Yee WONG, Hsin-Chu City (TW); Hsin-Yi HSIEH, Hsin-Chu City (TW)

(21) Appl. No.: 19/090,961

(22) Filed: Mar. 26, 2025

(51) Int. Cl. H01L 21/02; H01L 21/311; H10D 62/83

(52) U.S. Cl. CPC H10P 14/69215; H10D 62/83; H10P 14/6336; H10P 14/6526; H10P 50/282

(57) ABSTRACT

A method for forming a semiconductor structure is provided. The method for forming the semiconductor structure includes the following steps. A first deposition process is performed to form a first cladding layer over a substrate. A second deposition process is performed to form a second cladding layer directly on the first cladding layer. The first cladding layer and the second cladding layer are made of the same material, but with different film densities.

### BACKGROUND OF THE INVENTION

### Field of the Invention

The present disclosure relates to a semiconductor structure and a method for forming the same. In particular, the present disclosure relates to a semiconductor structure with two cladding layers made of the same material but different film densities and a method for forming the same.

### Description of the Related Art

In the process of fabricating semiconductor devices, it is often a challenge to control the etching process, especially when a structure has thin layers that remain. The challenge arises from the lack of selectivity during the etching process between layers made of the same material. In existing methods, etching in areas with different pattern loadings can lead to over-etching, resulting in unintended damage or performance issues.

Therefore, a novel method for forming a semiconductor that has remaining thinner layers is still in demand.

### BRIEF SUMMARY OF THE INVENTION

The present disclosure may address the challenges of controlling the etching process in structures with thin remaining layers by organizing two cladding layers made of the same material but with different film densities. The cladding layers may be formed through different deposition processes or the recipe parameters (e.g., oxygen flow or plasma power) during the formation processes may by adjusted, so that a thinner cladding layer may be left without causing unintended damage or performance issues.

An embodiment of the present invention provides a method for forming a semiconductor structure. The method for forming the semiconductor structure includes the following steps. A first deposition process is performed to form a first cladding layer over a substrate. A second deposition process is performed to form a second cladding layer directly on the first cladding layer. The first cladding layer and the second cladding layer are made of the same material, but with different film densities.

In some embodiments, the first deposition process and the second deposition process are different.

In some embodiments, the first deposition process is selected from one of the group consisting of a chemical vapor deposition, a plasma enhanced chemical vapor deposition, a high-density plasma vapor deposition, an electron beam evaporation, and a physical vapor deposition, and the second deposition process is selected from another one of the group consisting of a chemical vapor deposition, a plasma enhanced chemical vapor deposition, a high-density plasma vapor deposition, an electron beam evaporation, and a physical vapor deposition.

In some embodiments, the first cladding layer has a thickness within a range of 5 nm to 100 nm, or 20 nm to 50 nm.

In some embodiments, the first deposition process and the second deposition process have different deposition rates.

In some embodiments, the deposition rate of the first deposition process is slower than the deposition rate of the second deposition process.

In some embodiments, the first deposition process uses a different power level than the second deposition process.

some embodiments, the first deposition process uses a higher power level than the second deposition process.

In some embodiments, the method for forming a semiconductor structure further includes the following step. An ion implantation process is performed on the first cladding layer or the second cladding layer.

In some embodiments, the first deposition process and the second deposition process are the same.

In some embodiments, the first cladding layer and the second cladding layer includes silicon dioxide, and nitride ions are used for the ion implantation process.

In some embodiments, method for forming a semiconductor structure further includes the following step. The second cladding layer is patterned to form at least one trench, wherein the at least one trench exposes a portion of the first cladding layer.

In some embodiments, the method for forming a semiconductor structure further includes the following step. A waveguide is formed between the substrate and the first cladding layer.

In some embodiments, the first cladding layer has a thickness less than or equal to an evanescent wave region of the waveguide.

In some embodiments, the method for forming a semiconductor structure further includes the following step. A third cladding layer is formed between the substrate and the waveguide.

An embodiment of the present invention provides a semiconductor structure. The semiconductor structure includes a substrate and a first cladding layer disposed over the substrate. The semiconductor structure further includes a second cladding layer disposed on and in direct contact with the first cladding layer. The first cladding layer and the second cladding layer are made of the same material, but with different film densities.

In some embodiments, the first cladding layer or the second cladding layer has a doping ion, thereby creating the different film densities.

In some embodiments, the second cladding layer has at least one trench that exposes a portion of the first cladding layer.

In some embodiments, the semiconductor structure further includes a waveguide disposed between the substrate and the first cladding layer.

In some embodiments, the first cladding layer and the second cladding layer includes silicon dioxide or silicon nitride.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a partial cross-sectional view illustrating the semiconductor according to some embodiments of the present disclosure.

FIG. 2A to FIG. 2G are partial cross-sectional views illustrating a method for forming the semiconductor structure at various stages according to some embodiments of the present disclosure.

FIG. 3 illustrates a partial optical emission spectroscopy (OES) signal while etching through the semiconductor structure.

FIG. 4 is a real cross-sectional view of the semiconductor structure under scanning electron microscope (SEM).

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

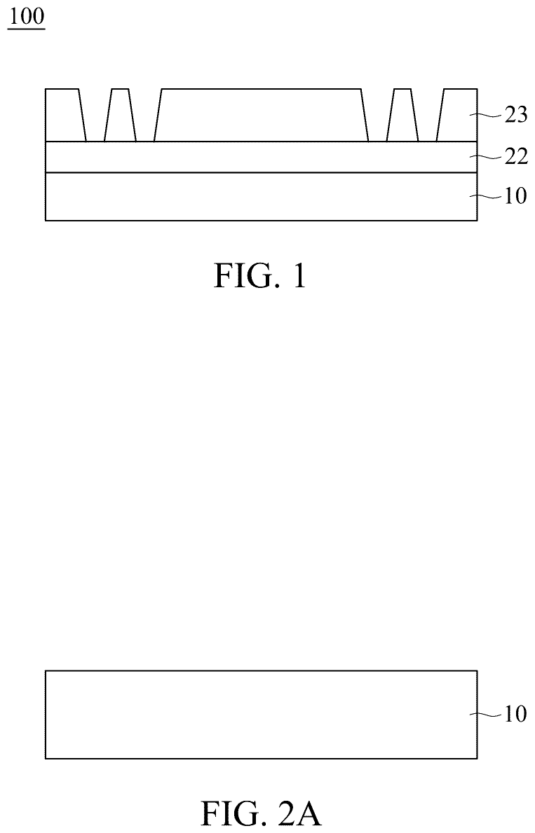

FIG. 1 is a partial cross-sectional view illustrating the semiconductor 100 according to some embodiments of the present disclosure. It should be noted that some components of the semiconductor 100 have been omitted in FIG. 1 for the sake of brevity.

Referring to FIG. 1, in some embodiments, the semiconductor 100 includes a substrate 10. For example, the substrate 10 may include an elementary semiconductor (e.g., silicon or germanium), a compound semiconductor (e.g., silicon carbide (SiC), gallium arsenic (GaAs), indium arsenide (InAs), or indium phosphide (InP)), an alloy semiconductor (e.g., silicon germanium (SiGe), silicon germanium carbide (SiGeC), gallium arsenic phosphide (GaAsP), or gallium indium phosphide (GaInP)), any other applicable semiconductor, or a combination thereof. Moreover, the substrate 10 may be a semiconductor-on-insulator (SOI) substrate that includes a bottom substrate, a buried oxide layer disposed on the bottom substrate, and a semiconductor layer disposed on the buried oxide layer. In some examples, the substrate 10 may be a semiconductor wafer (e.g., a silicon wafer, or any other applicable semiconductor wafer).

The substrate 10 may include various p-type doped regions and/or n-type doped regions formed by a process such as an ion implantation process and/or a diffusion process. For example, the doped regions may be configured to form a transistor, a photodiode, and/or a light-emitting diode, but the present disclosure is not limited thereto. Further, the substrate 10 may include various isolation features to separate various device regions in the substrate 10. For example, the isolation features may include a shallow trench isolation (STI) feature, but the present disclosure is not limited thereto. The formation of a shallow trench isolation (STI) feature may include etching a trench in the substrate 10 and filling in the trench with insulating materials (e.g., silicon oxide, silicon nitride, or silicon oxynitride). The filled trench may have a multi-layer structure, such as a thermal oxide liner layer with silicon nitride filling the trench. A chemical mechanical polishing (CMP) process may be performed to polish back excessive insulating materials and planarize the top surface of the isolation features. Furthermore, the substrate 10 may include various conductive features (e.g., conductive lines or vias). For example, the conductive features may be made of aluminum (Al), copper (Cu), tungsten (W), an alloy thereof, any other applicable conductive material, or a combination thereof.

Referring to FIG. 1, in some embodiments, the semiconductor 100 includes an upper cladding layer 22 and an upper cladding layer 23. The upper cladding layer 22 is disposed over the substrate 10, and the upper cladding layer 23 is disposed on and in direct contact with the upper cladding layer 22. In some embodiments, the upper cladding layer 22 and the upper cladding layer 23 are made of the same material, but with different film densities. Here, different film densities indicate that the molecules in the upper cladding layer 22 and the upper cladding layer 23 may have different arrangements, which may be achieved through different deposition processes, adjusting different process parameters, or doping different ions, but the present disclosure is not limited thereto.

In some embodiments, the upper cladding layer 22 and the upper cladding layer 23 includes silicon dioxide (SiO₂), silicon nitride (SiN), any other applicable material, or a combination thereto. The upper cladding layer 22 and the upper cladding layer 23 may be formed by a deposition process, such as a chemical vapor deposition (CVD), a plasma enhanced chemical vapor deposition (PECVD), a high-density plasma vapor deposition (HD-CVD), an electron beam evaporation (E-gun), and a physical vapor deposition (e.g., sputter deposition), but the present disclosure is not limited thereto.

In some embodiments, the upper cladding layer 22 or the upper cladding layer 23 has a doping ion, thereby creating the different film densities. For example, the upper cladding layer 22 and the upper cladding layer 23 may both be formed of silicon dioxide (SiO₂), and one of which is doped with nitride ions, but the present disclosure is not limited thereto.

As shown in FIG. 1, in some embodiments, the upper cladding layer 23 has at least one trench 23T that exposes a portion of the upper cladding layer 22. For example, an etching process may be performed on the upper cladding layer 23 to form at least one trench 23T. Since the upper cladding layer 22 and the upper cladding layer 23 have different film densities, the upper cladding layer 22 may be used as a stopping layer during the etching process. In more detail, due to the film densities, under the same etching parameters, the etching rate for the upper cladding layer 23 is faster than the etching rate for the upper cladding layer 22, with the etching rate possibly being 1.05 to 5 times higher. As a result, the etching stop position mat be controlled at the position of the upper cladding layer 22.

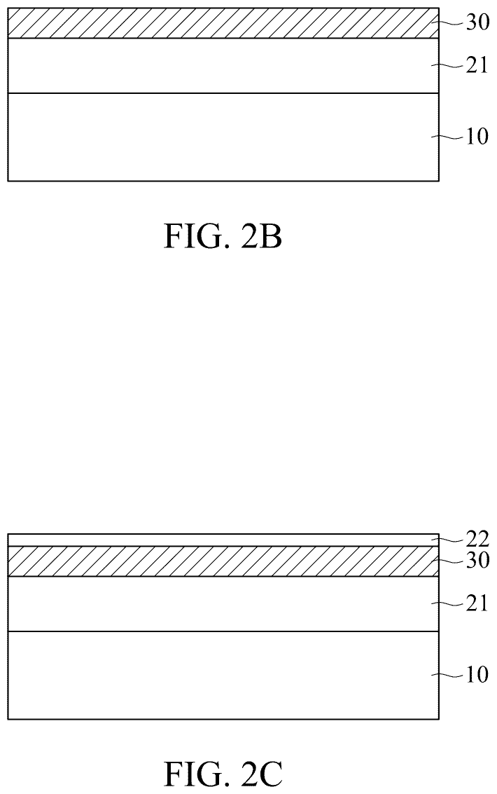

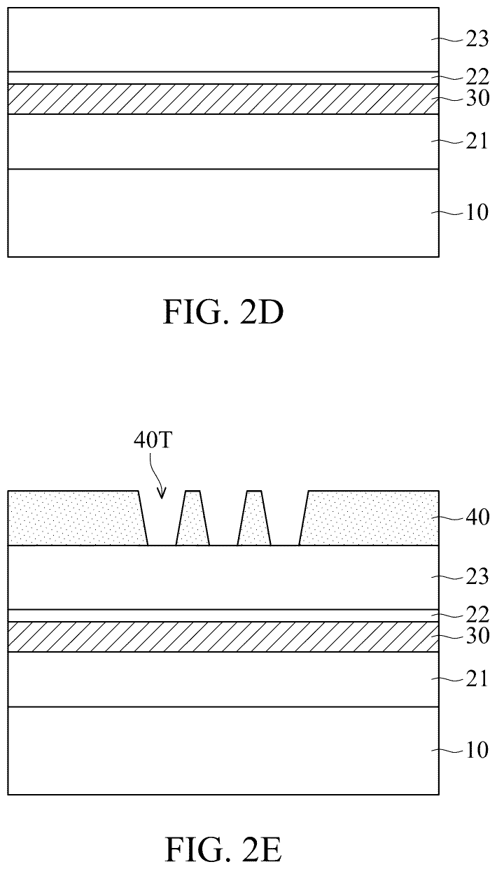

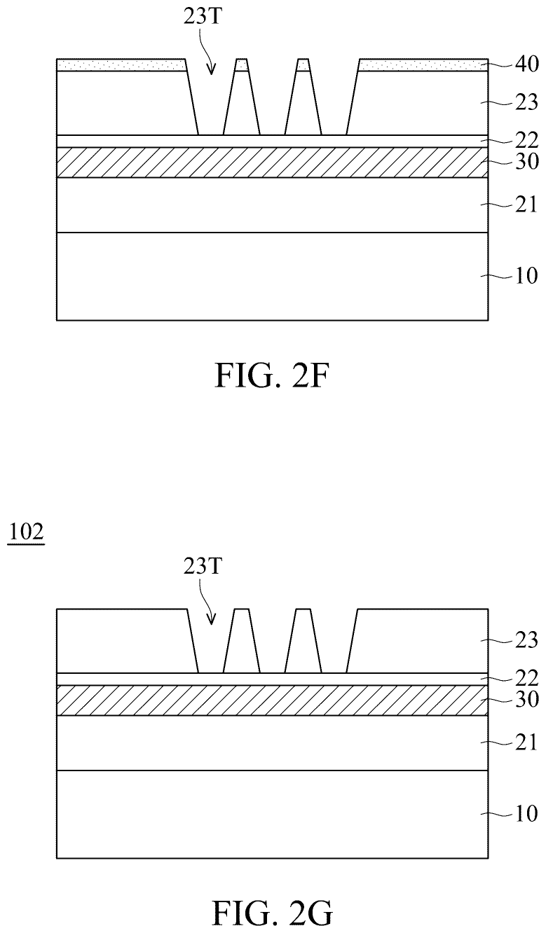

FIG. 2A to FIG. 2G are partial cross-sectional views illustrating a method for forming the semiconductor structure 102 at various stages according to some embodiments of the present disclosure. It should be noted that some components of the semiconductor structure 102 have been omitted in FIG. 2A to FIG. 2G for the sake of brevity.

Referring to FIG. 2A, in some embodiments, a substrate 10 is provided. Referring to FIG. 2B, in some embodiments, a lower cladding layer 21 is formed on the substrate 10. For example, the lower cladding layer 21 may include any suitable dielectric material, such as silicon oxide, silicon nitride, silicon oxynitride, low-κ dielectric material, aluminum oxide, aluminum nitride, the like, or a combination thereof, but the present disclosure is not limited thereto. Moreover, the lower cladding layer 21 may be formed by a deposition process, such as a chemical vapor deposition, an atomic layer deposition, a spin coating, the like, or a combination thereof, but the present disclosure is not limited thereto. Then, in some embodiments, a waveguide 30 is formed on the lower cladding layer 21. In more detail, the lower cladding layer 21 is formed between the substrate 10 and the waveguide 30. The waveguide 30 may be formed by a deposition process, examples of which have been described above and will not be repeated here.

Referring to FIG. 2C, in some embodiments, a first deposition process is performed to form an upper cladding layer 22 over the substrate 10. In more detail, the waveguide 30 is formed between the substrate 10 and the upper cladding layer. In some embodiments, the first deposition process is selected from one of the group consisting of a chemical vapor deposition (CVD), a plasma enhanced chemical vapor deposition (PECVD), a high-density plasma vapor deposition (HDPVD), an electron beam evaporation (E-gun), and a physical vapor deposition (PVD). In some embodiments, the physical vapor deposition includes a sputter deposition.

Referring to FIG. 2D, in some embodiments, a second deposition process is performed to form an upper cladding layer 23 directly on the upper cladding layer 22, and the upper cladding layer 22 and the upper cladding layer 23 are made of the same material, but with different film densities. Here, the upper cladding layer 22 has a thinner thickness than the upper cladding layer 23. In some embodiments, the upper cladding layer 22 has a thickness within a range of about 5 nm to about 100 nm, or 20 nm to about 50 nm. In some embodiments, the upper cladding layer 22 has a thickness less than or equal to the evanescent wave region of the waveguide 30, which is usually the length where the intensity decays to 1/e. Moreover, the upper cladding layer 23 may have a thickness within a range of about 30 nm to about 2000 nm, or 50 nm to about 500 nm.

In some embodiments, the first deposition process and the second deposition process are different. In some embodiments, the second deposition process is selected from another one of the group consisting of a chemical vapor deposition(CVD), a plasma enhanced chemical vapor deposition (PECVD), a high-density plasma vapor deposition (HDPVD), an electron beam evaporation (E-gun), and a physical vapor deposition (PVD).

In one embodiment, the first deposition process is an electron beam evaporation, and the second deposition process is a chemical vapor deposition. In another embodiment, the first deposition process is an electron beam evaporation, and the second deposition process is a physical vapor deposition. In still another embodiment, the first deposition process is chemical vapor deposition, and the second deposition process is a physical vapor deposition. The different deposition processes may cause different film densities of the upper cladding layer 22 and the upper cladding layer 23, but the present disclosure is not limited thereto.

In some embodiments, the first deposition process and the second deposition process have different deposition rates, thereby causing different film densities of the upper cladding layer 22 and the upper cladding layer 23. In some embodiments, the deposition rate of the first deposition process (for the upper cladding layer 22) is slower than the deposition rate of the second deposition process (for the upper cladding layer 23). For example, when the upper cladding layer 22 and the upper cladding layer 23 are formed of silicon dioxide, the silicon dioxide flow rate during the first deposition process may be greater than or less than the silicon dioxide flow rate during the second deposition process.

In some embodiments, the first deposition process uses a different power level than the second deposition process, thereby causing the upper cladding layer 22 and the upper cladding layer 23 to have different film densities. In some embodiments, the first deposition process uses a higher power level (e.g., plasma power) than the second deposition process.

In some other embodiments, an ion-assisted deposition (IAD) with optional higher deposition temperature or lower deposition rate is applied, so that the density and the hardness of the deposited film (e.g., upper cladding layer 22 and/or upper cladding layer 23) is higher.

In some other embodiments, the first deposition process and the second deposition process are the same. In some embodiments, an ion implantation process is performed on the upper cladding layer 22 or the upper cladding layer 23, thereby causing different film densities of the upper cladding layer 22 and the upper cladding layer 23. For example, the ion implantation process may be performed on the upper cladding layer 22 before the second deposition process. Alternatively, the ion implantation process may be performed on the upper cladding layer 23 after the second deposition process. In some embodiments, the upper cladding layer 22 and the upper cladding layer 23 includes silicon dioxide, and nitride ions are used for the ion implantation process, but the present disclosure is not limited thereto.

Referring to FIG. 2E to FIG. 2G, in some embodiments, the upper cladding layer 23 is patterned to form at least one trench 23T that exposes a portion of the upper cladding layer 22. For example, as shown in FIG. 2E, a mask layer 40 have multiple holes 40T may be formed on the upper cladding layer 23. Then, as shown in FIG. 2F, an etching process may be performed to etch the upper cladding layer 23 using the mask layer 40 as an etch mask. For example, the mask layer 40 may include a photoresist, such as a positive photoresist or a negative photoresist. Moreover, the mask layer 40 may be a hard mask that includes silicon oxide (SiO₂), silicon nitride (SiN), silicon oxynitride (SiON), silicon carbide (SiC), silicon carbonitride (SiCN), the like, or a combination thereof, but the present disclosure is not limited thereto. The mask layer 40 may be a single-layer structure or a multi-layer structure. The mask layer 40 may be formed by a deposition process, a photolithography process, other suitable processes, or a combination thereof, but the present disclosure is not limited thereto.

For example, the deposition process may include spin-on coating, chemical vapor deposition (CVD), atomic layer deposition (ALD), the like, or a combination thereof. For example, the photolithography process may include photoresist coating (e.g., spin coating), soft baking, mask aligning, exposure, post-exposure baking (PEB), developing, rinsing, drying (e.g., hard baking), other suitable processes, or a combination thereof, but the present disclosure is not limited thereto.

The etching process may include a dry etching process, a wet etching process, or a combination thereof. For example, the dry etching process may include reactive ion etch (RIE), inductively-coupled plasma (ICP) etching, neutral beam etching (NBE), electron cyclotron resonance (ERC) etching, the like, or a combination thereof, but the present disclosure is not limited thereto. For example, the wet etching process may use hydrofluoric acid (HF), ammonium hydroxide (NH₄OH), any suitable etchant, or a combination thereof, but the present disclosure is not limited thereto.

In the present disclosure, since the upper cladding layer 22 and the upper cladding layer 23 have different film densities, the upper cladding layer 22 may be used as a stopping layer during the etching process, so that a portion of the upper cladding layer 22 is exposed. Then, as shown in FIG. 2G, the mask layer 40 is removed.

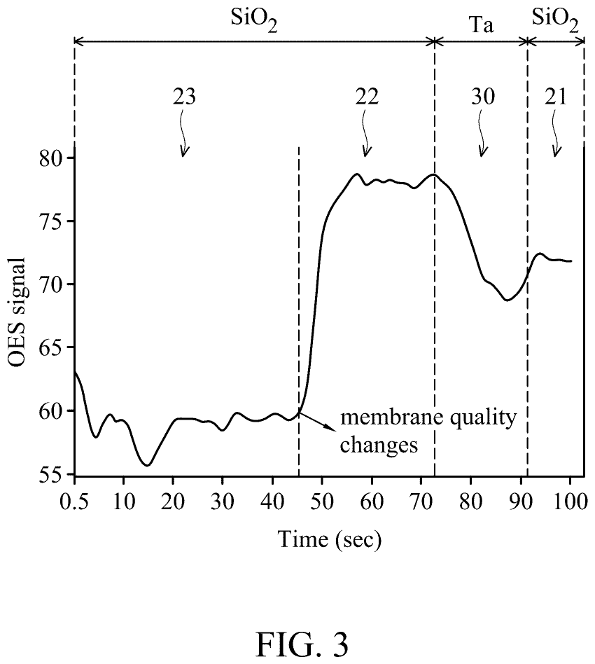

FIG. 3 illustrates a partial optical emission spectroscopy (OES) signal while etching through the semiconductor structure 102. As shown in FIG. 3, in this embodiment, the upper cladding layer 22 and the upper cladding layer 23 have the same material (i.e., silicon dioxide (SiO₂)) but different film densities, so that there is an obvious signal difference (e.g., >5) at the junction of the upper cladding layer 22 and the upper cladding layer 23, or the occurrence of the pre-doping element in the upper cladding layer 22. That is, the membrane quality changes significantly.

For example, the difference between the etching rate of the upper cladding layer 22 and the etching rate of the upper cladding layer 23 may be greater than 5%, 10% or more than 20 %, but the present disclosure is not limited thereto. As long as a noticeable signal variation occurs (e.g., differences in elements or distinguishable etching rates), the etching equipment may be set to manually or automatically terminate the etching process. This ensures that the etching stop layer appears at a shallow depth within the upper cladding layer 22, allowing for precise control of the etching stop position.

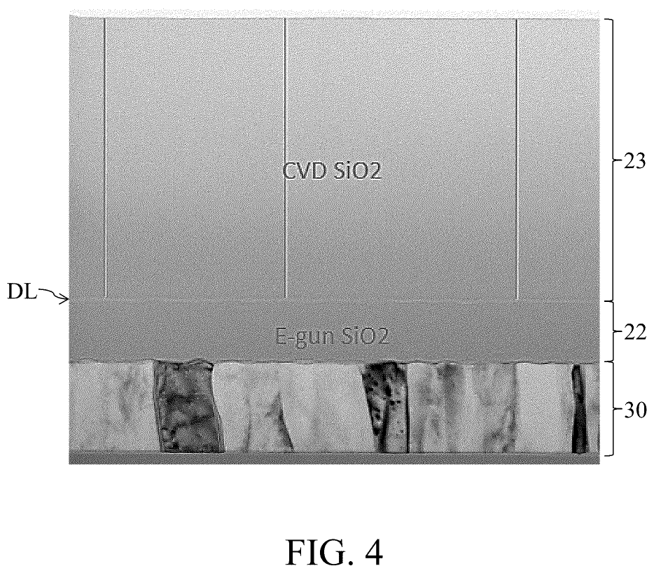

FIG. 4 is a real cross-sectional view of the semiconductor structure 102 under scanning electron microscope (SEM). In this embodiment, the upper cladding layer 22 and the upper cladding layer 23 are both formed of silicon dioxide (SiO₂), while the upper cladding layer 22 is formed by an electron beam evaporation (E-gun), and the upper cladding layer 23 is formed by a chemical vapor deposition CVD. As shown in FIG. 4, there is a clear dividing line DL between the upper cladding layer 22 and the upper cladding layer 23. That is, the upper cladding layer 22 and the upper cladding layer 23 have the same material but different film densities.

As noted above, in the embodiments of the present disclosure, the challenges of controlling the etching process in structures with thin remaining layers (e.g., the upper cladding layer 22) may be addressed by organizing two cladding layers made of the same material but with different film densities. The cladding layers may be formed through different deposition processes or the recipe parameters (e.g., oxygen flow or plasma power) during the formation processes may by adjusted, so that a thinner cladding layer may be left without unintended damage or performance issues.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A method for forming a semiconductor structure, comprising:
performing a first deposition process to form a first cladding layer over a substrate; and
performing a second deposition process to form a second cladding layer directly on the first cladding layer,
wherein the first cladding layer and the second cladding layer are made of the same material, but with different film densities.

2. The method for forming a semiconductor structure as claimed in claim 1, wherein the first deposition process and the second deposition process are different.

3. The method for forming a semiconductor structure as claimed in claim 2, wherein the first deposition process is selected from one of the group consisting of a chemical vapor deposition, a plasma enhanced chemical vapor deposition, a high-density plasma vapor deposition, an electron beam evaporation, and a physical vapor deposition, and the second deposition process is selected from another one of the group consisting of a chemical vapor deposition, a plasma enhanced chemical vapor deposition, a high-density plasma vapor deposition, an electron beam evaporation, and a physical vapor deposition.

4. The method for forming a semiconductor structure as claimed in claim 1, wherein the first cladding layer has a thickness within a range of 5 nm to 100 nm, or 20 nm to 50 nm.

5. The method for forming a semiconductor structure as claimed in claim 1, wherein the first deposition process and the second deposition process have different deposition rates.

6. The method for forming a semiconductor structure as claimed in claim 5, wherein the deposition rate of the first deposition process is slower than the deposition rate of the second deposition process.

7. The method for forming a semiconductor structure as claimed in claim 1, wherein the first deposition process uses a different power level than the second deposition process.

8. The method for forming a semiconductor structure as claimed in claim 7, wherein the first deposition process uses a higher power level than the second deposition process.

9. The method for forming a semiconductor structure as claimed in claim 1, further comprising:
performing an ion implantation process on the first cladding layer or the second cladding layer.

10. The method for forming a semiconductor structure as claimed in claim 9, wherein the first deposition process and the second deposition process are the same.

11. The method for forming a semiconductor structure as claimed in claim 9, wherein the first cladding layer and the second cladding layer comprises silicon dioxide, and nitride ions are used for the ion implantation process.

12. The method for forming a semiconductor structure as claimed in claim 1, further comprising:
patterning the second cladding layer to form at least one trench, wherein the at least one trench exposes a portion of the first cladding layer.

13. The method for forming a semiconductor structure as claimed in claim 1, further comprising:
forming a waveguide between the substrate and the first cladding layer.

14. The method for forming a semiconductor structure as claimed in claim 13, wherein the first cladding layer has a thickness less than or equal to an evanescent wave region of the waveguide.

15. The method for forming a semiconductor structure as claimed in claim 13, further comprising:
forming a third cladding layer between the substrate and the waveguide.

16. A semiconductor structure, comprising:
a substrate;
a first cladding layer disposed over the substrate; and
a second cladding layer disposed on and in direct contact with the first cladding layer, wherein the first cladding layer and the second cladding layer are made of the same material, but with different film densities.

17. The semiconductor structure as claimed in claim 16, wherein the first cladding layer or the second cladding layer has a doping ion, thereby creating the different film densities.

18. The semiconductor structure as claimed in claim 16, wherein the second cladding layer has at least one trench that exposes a portion of the first cladding layer.

19. The semiconductor structure as claimed in claim 16, further comprising:
a waveguide disposed between the substrate and the first cladding layer.

20. The semiconductor structure as claimed in claim 16, wherein the first cladding layer and the second cladding layer comprises silicon dioxide or silicon nitride.
